(19) United States
(12) Patent Application Publication
(10) Pub. No.: US 2013/0126984 A1
(43) Pub. Date: May 23, 2013

(54) Patterning of Sensitive Metal-Containing Layers With Superior Mask Material Adhesion by Providing a Modified Surface Layer

(71) Applicants: Berthold Reimer, Dresden (DE); Martin Trentzsch, Dresden (DE); Erwin Grund, Moritzburg (DE); Sven Beyer, Dresden (DE)

(72) Inventors: Berthold Reimer, Dresden (DE); Martin Trentzsch, Dresden (DE); Erwin Grund, Moritzburg (DE); Sven Beyer, Dresden (DE)

(73) Assignee: GLOBALFOUNDRIES INC., Grand Cayman (KY)

(21) Appl. No.: 13/301,981

(22) Filed: Nov. 22, 2011

(51) Int. Cl. H01L 29/772; H01L 21/28

(52) U.S. Cl. 257/410; 438/592; 438/585; 257/E21.19; 257/E29.242

(57) ABSTRACT

When patterning metal-containing material layers, such as titanium nitride, in critical manufacturing stages, for instance upon forming sophisticated high-k metal gate electrode structures or providing hard mask materials for patterning a metallization system, the surface adhesion of a resist material on the titanium nitride material may be improved by applying a controlled oxidation process.

### BACKGROUND OF THE INVENTION

1. Field of the Invention

Generally, the present disclosure relates to the fabrication of sophisticated integrated circuits including transistor elements formed on the basis of metal-containing metal layers, for example, in the form of titanium nitride, used during critical patterning processes, such as forming a high-k metal gate structure, providing hard mask layers and the like.

2. Description of the Related Art

The fabrication of advanced integrated circuits, such as CPUs, storage devices, ASICs (application specific integrated circuits) and the like, requires the formation of a large number of circuit elements on a given chip area according to a specified circuit layout. Since performance and packing density typically increase by reducing the lateral dimensions of the individual circuit elements, in modern integrated circuits, critical dimensions of a hundred nanometers and significantly less have been implemented, thereby requiring sophisticated patterning techniques. During critical patterning processes, frequently, metal-containing material layers, such as layers in the form of titanium nitride and the like, have to be etched, typically on the basis of wet chemical etch recipes, wherein, nevertheless, precisely defined lateral dimensions and thus precisely adapted under-etched areas are required. For example, titanium nitride may be used as an efficient hard mask material when patterning the dielectric material of metallization layers, thereby requiring precisely defined lateral dimensions of the hard mask material in order to obtain metal lines and vias of the metallization layer under consideration in compliance with the overall design rules.

In other critical phases of the overall manufacturing process, titanium nitride and other metal-containing material layers may be used upon forming sophisticated gate electrode structures of field effect transistors. That is, in a wide variety of integrated circuits, field effect transistors represent one important type of circuit element that substantially determines performance of the integrated circuits. Generally, a plurality of process technologies are currently practiced for forming field effect transistors, wherein, for many types of complex circuitry, MOS technology is one of the most promising approaches due to the superior characteristics in view of operating speed and/or power consumption and/or cost efficiency. During the fabrication of complex integrated circuits using, for instance, MOS technology, millions of transistors, e.g., N-channel transistors and/or P-channel transistors, are formed on a substrate including a crystalline semiconductor layer. A field effect transistor, irrespective of whether an N-channel transistor or a P-channel transistor is considered, typically comprises so-called PN junctions that are formed by an interface of highly doped regions, referred to as drain and source regions, with a slightly doped or non-doped region, such as a channel region, disposed adjacent to the highly doped regions. In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends on, among other things, the dopant concentration, the mobility of the charge carriers and, for a given extension of the channel region in the transistor width direction, the distance between the source and drain regions, which is also referred to as channel length. Hence, the conductivity of the channel region substantially affects the performance of MOS transistors. Thus, the scaling of the channel length, and associated therewith the reduction of channel resistivity, which in turn causes an increase of gate resistivity due to the reduced dimensions, is a dominant design criterion for accomplishing an increase in the operating speed of the integrated circuits.

Presently, the vast majority of integrated circuits are based on silicon due to its substantially unlimited availability, the well-understood characteristics of silicon and related materials and processes and the experience gathered during the last 50 years. Therefore, silicon will likely remain the material of choice for future circuit generations to be fabricated by using volume production techniques. One reason for the dominant role of silicon in fabricating semiconductor devices has been the superior characteristics of a silicon/silicon dioxide interface that allows reliable electrical insulation of different regions from each other. The silicon/silicon dioxide interface is stable at high temperatures and, thus, allows the performance of subsequent high temperature processes, as are required, for example, during anneal cycles to activate dopants and to cure crystal damage without sacrificing the electrical characteristics of the interface.

For the reasons pointed out above, in field effect transistors, silicon dioxide is preferably used as a base material of a gate insulation layer that separates the gate electrode, frequently comprised of polysilicon, from the silicon channel region. In steadily improving device performance of field effect transistors, the length of the channel region has been continuously decreased to improve switching speed and drive current capability. Since transistor performance is controlled by the voltage supplied to the gate electrode to invert the surface of the channel region to a sufficiently high charge density for providing the desired drive current for a given supply voltage, a certain degree of capacitive coupling, provided by the capacitor formed by the gate electrode, the channel region and the silicon dioxide disposed therebetween, has to be maintained. It turns out that decreasing the channel length requires an increased capacitive coupling to avoid the so-called short channel behavior during transistor operation. Aggressively scaled transistor devices with a relatively low supply voltage and thus reduced threshold voltage may suffer from an exponential increase of the leakage current, since the thickness of the silicon dioxide layer has to be correspondingly decreased to provide the required capacitance between the gate and the channel region. For example, a channel length of approximately 80 nm may require a gate dielectric made of silicon dioxide as thin as approximately 1.2 nm. The relatively high leakage current caused by direct tunneling of charge carriers through an ultra-thin silicon dioxide-based gate insulation layer may reach values for an oxide thickness in the range of 1-2 nm that may not be compatible with requirements for many types of circuits, even if only transistors in speed critical paths are formed on the basis of an extremely thin gate oxide.

Therefore, replacing silicon dioxide as the material for gate insulation layers has been considered, particularly for field effect transistors, which would otherwise require extremely thin silicon dioxide gate layers. Possible alternative materials include materials that exhibit a significantly higher permittivity so that a physically greater thickness of a correspondingly formed gate insulation layer provides a capacitive coupling that would be obtained by an extremely thin silicon dioxide layer. It has thus been suggested to replace silicon dioxide with high permittivity materials such as tantalum oxide (Ta₂O₅), with a k of approximately 25, strontium titanium oxide (SrTiO₃), having a k of approximately 150, hafnium oxide (HfO₂), HfSiO, zirconium oxide (ZrO₂) and the like.

Additionally, transistor performance may be enhanced by providing an appropriate conductive material for the gate electrode so as to replace the usually used polysilicon material, since polysilicon may suffer from charge carrier depletion at the vicinity of the interface to the gate dielectric, thereby reducing the effective capacitance between the channel region and the gate electrode. Thus, a gate stack has been suggested in which a high-k dielectric material provides an increased capacitance, while additionally leakage currents are kept at an acceptable level. On the other hand, the non-polysilicon material, such as titanium nitride and the like, may be formed so as to connect to the high-k dielectric material, thereby substantially avoiding the presence of a depletion zone.

Hence, a plurality of process strategies have been developed in order to provide sophisticated gate electrode structures including a high-k dielectric material in combination with an appropriate metal-containing electrode material, such as titanium nitride and the like. In some of these approaches, the gate electrode structures are provided in an early manufacturing stage so as to include the sensitive high-k dielectric material and the metal-containing electrode material, thereby typically requiring one or more patterning processes in an early manufacturing stage, i.e., prior to forming a complete gate layer stack and patterning the same so as to obtain gate electrode structures that comply with the required lateral dimensions. In other approaches, the high-k dielectric material and at least one metal-containing cap material may be provided in an early manufacturing stage, while the final electronic characteristics of the gate electrode structures may be established in a very advanced manufacturing stage, i.e., after completing the basic transistor structures. In this case, at least a highly conductive electrode metal is provided in a late manufacturing stage in which a place-holder material, such as polysilicon, is replaced with at least the highly conductive electrode metal. Furthermore, depending on the process strategy in this late manufacturing stage, also other materials, such as the high-k dielectric material, possibly in combination with appropriate work function metal species, may be incorporated into the gate electrode structures, thereby also requiring sophisticated patterning strategies in order to provide gate electrode structures with appropriate electronic characteristics that correspond to the various types of transistors to be provided. As a consequence, irrespective of the process strategy applied, typically, the patterning of a metal-containing electrode material, such as titanium nitride and the like, has to be applied in order to complete the sophisticated gate electrode structures. Since these metal-containing materials, for instance in the form of titanium nitride, are frequently patterned on the basis of well-established wet chemical etch recipes, a certain degree of under-etching may be obtained, which, however, has to be adjusted to a well-defined range in order to comply with the further processing of the device in which well-defined lateral dimensions have to be implemented. With reference to FIG. 1, a typical sophisticated manufacturing process will now be described in which a titanium nitride material has to be patterned upon forming a sophisticated gate electrode structure by using highly efficient wet chemical etch recipes.

FIG. 1 schematically illustrates a cross-sectional view of a semiconductor device 100 in a manufacturing stage in which gate electrode structures have to be formed above a semiconductor layer 102, which may be provided in the form of a silicon material, a silicon/germanium material and the like. Furthermore, the semiconductor layer 102 is provided above a substrate 101, such as a semiconductor substrate or any other appropriate carrier material for receiving the semiconductor layer 102 thereon. It should be appreciated that generally the semiconductor layer 102 and the substrate 101 may define a silicon-on-insulator (SOI) architecture when a buried insulating material (not shown) is provided between the substrate 101 and the semiconductor layer 102. In other cases, the semiconductor layer 102 and the substrate 101 may represent a bulk configuration in which the crystalline semiconductor material of the layer 102 is in direct contact with a crystalline semiconductor material of the substrate 101. At any appropriate manufacturing stage in forming gate electrode structures, a gate dielectric layer 161 is formed on the semiconductor layer 102 and may, as discussed above, comprise a high-k dielectric material, for instance in the form of one or more of the high-k dielectric materials specified above. It should be appreciated that the gate dielectric layer 161 may additionally comprise a conventional dielectric material, such as silicon dioxide and the like, if any such material is required, for instance with respect to providing superior interface characteristics and the like. Furthermore, a titanium nitride layer 162 is formed on the gate dielectric layer 161 and may have any appropriate layer thickness, for instance in the range of 5 nm and less, depending on the overall process strategy. As discussed above, depending on the overall process strategy, it may be necessary at some stage of the overall process flow to appropriately pattern at least the layer 162, which is typically accomplished on the basis of well-established wet chemical etch recipes using, for instance, APM (ammonium hydroxide/hydrogen peroxide mixture), which may be provided in the form of an aqueous solution, wherein a concentration of APM in the de-ionized water, as well as the temperature of the solution, may be appropriately selected, for instance by performing experiments and the like, in order to obtain a desired etch rate upon patterning the titanium nitride layer 162.

Typically the layers 161 and 162 may be formed on the basis of well-established process techniques, for instance, by highly controllable deposition processes in the form of chemical vapor deposition (CVD), self-limiting CVD, such as atomic layer deposition (ALD), and the like, possibly in combination with surface treatment processes, such as oxidation, if conventional dielectric materials have to be incorporated into the gate dielectric layer 161. Thereafter, the titanium nitride layer 162 may be formed, for instance, by physical vapor deposition (PVD), ALD and the like, in order to provide the desired thickness and material composition. It should be appreciated that, prior to forming the layers 161 and 162, other processes may be applied, such as the formation of isolation structures (not shown), which may divide the semiconductor layer 102 into a plurality of active regions, which are to be understood as semiconductor regions of the layer 102 in and above which one or more corresponding transistors are to be formed.

Thereafter, in some approaches, a resist mask 103 is formed directly on the titanium nitride layer 162, which may be accomplished by applying well-established lithography techniques, i.e., the deposition of a resist material, the exposure of the resist material and the development of the resist material, wherein any appropriate pre- and post-resist deposition processes may be applied. In this manner, the mask 103 is obtained so as to substantially correspond to the required lateral dimensions in order to appropriately pattern the layer 162, possibly in combination with the layer 161. For example, frequently, the titanium nitride material 162 has to be removed from above certain active regions in order to differently adjust the electronic characteristics of the gate electrode structures still to be formed. As discussed above, typically, precisely defined lateral dimensions have to be adjusted during the patterning of the layer 162, which requires a precise adjustment of the lateral dimensions of the resist mask 103. Thereafter, a wet chemical etch process 104 is applied, for instance, based on the above-identified recipes, thereby highly efficiently removing the exposed portion of the layer 162. Due to the isotropic etch behavior of the wet chemical etch process 104, however, a certain degree of under-etching, as indicated by 162u, is typically observed, which has to be taken into consideration when selecting appropriate lateral dimensions for the resist mask 103. Generally, for a given wet chemical etch recipe, the etch rate may be determined in advance with a high degree of accuracy, a well-defined under-etched area would be expected to be created during the process 104. It is observed, however, that a significantly increased degree of under-etching 162u may occur, wherein additionally a finally achieved under-etched area 162u may have highly non-uniform lateral dimensions, since the degree of under-etching may depend in a highly non-predictable manner from a plurality of process parameters. Since the patterning of the layer 162 may have a significant influence on the finally obtained electronic characteristics of the gate electrode structures still to be formed, for instance a varying effective gate width may be obtained, the implementation of a patterning process based on the resist mask 103 and the wet chemical etch process 104 into volume production techniques is less than desirable. Therefore, significant efforts have been made in order to determine the reason for the non-predictable degree of under-etching of the resist mask 103. Without intending to restrict the present application to the following explanation, it is presently believed that reduced adhesion of the resist material 103 on the surface of the layer 162 is a dominant failure mechanism since the resulting interface 103i between the material 103 and 162 may cause lateral migration of etch chemicals along the interface 103i, thereby causing pronounced etch damage and thus increasing the under-etched area 162u in a highly non-predictable manner. Therefore, alternative approaches have been suggested in which a moderately long time interval is introduced between the deposition of the titanium nitride layer 162 and the resist material 103 in order to provide superior adhesion. In this case, however, in particular in volume production environments, a highly complex scheduling regime has to be implemented, thereby also significantly reducing the overall cycle time for a given amount of resources in terms of process tools. In other alternative approaches, it has been suggested to provide a hard mask material, for instance in the form of well-established dielectric materials, such as silicon dioxide and the like, in order to obtain superior interface characteristics. In this case, however, additional deposition processes may be required, followed by appropriate removal processes in order to remove the previously provided hard mask material, which in turn may increase overall process complexity and may also cause additional etch damage upon removing the hard mask material.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides manufacturing techniques and semiconductor devices in which metal-containing materials, such as titanium nitride and the like, may be patterned in accordance with a process strategy in which a hard mask material may not be required. It has been recognized that a surface treatment of the metal-containing material may result in superior adhesion to organic materials, such as resist materials or any other polymer materials, thereby enabling the formation of an etch mask on the basis of the organic material having the superior adhesion to the underlying metal-containing electrode material. In this manner, an etch mask comprised of organic material may be efficiently used in order to obtain well-defined lateral dimensions of the metal-containing material layer since the degree of under-etching may be predicted in a highly precise manner.

In some illustrative embodiments disclosed herein, the surface modification comprises the incorporation of oxygen species into the metal-containing material layer, thereby forming an oxidized layer portion providing superior adhesion between the oxidized layer and the organic mask material. In some illustrative embodiments, the surface treatment may be based on a self-limiting oxidation process, thereby providing a well-defined thickness of the modified surface layer so that generally the overall characteristics of the metal-containing material layer, even after providing the modified surface layer, may be adjusted in a well-defined manner.

One illustrative method disclosed herein comprises performing a surface treatment on a metal-containing material layer that is formed above a substrate of a semiconductor device, wherein the surface treatment results in the incorporation of oxygen into the metal-containing material layer. The method further comprises forming an organic mask on a surface of the metal-containing material layer after the surface treatment. Additionally, the method comprises performing a wet chemical etch process and using the organic mask as an etch mask so as to pattern the metal-containing material layer.

A further illustrative method disclosed herein comprises forming an oxidized surface layer in a titanium and nitrogen-containing material. The method further comprises forming an etch mask on the oxidized surface layer and performing an etch process in the presence of the etch mask so as to pattern the titanium and nitrogen-containing material.

One illustrative semiconductor device disclosed herein comprises a gate electrode structure comprising a high-k gate insulation layer, a metal-containing first electrode material formed on the high-k gate insulation layer and a second electrode material formed above the metal-containing first electrode material. The metal-containing first electrode material comprises an oxygen-containing surface layer having a thickness of approximately 2 nm or less.

### BRIEF DESCRIPTION OF THE DRAWINGS

The disclosure may be understood by reference to the following description taken in conjunction with the accompanying drawings, in which like reference numerals identify like elements, and in which:

FIG. 1 schematically illustrates a cross-sectional view of a semiconductor device during a patterning process for etching a titanium nitride layer on the basis of a wet chemical etch chemistry using conventional process strategies;

FIGS. 2a-2f schematically illustrate cross-sectional views of a semiconductor device during various manufacturing stages when forming sophisticated gate electrode structures requiring the patterning of metal-containing electrode materials, according to illustrative embodiments; and

FIGS. 3a-3b schematically illustrate cross-sectional views of a semiconductor device during various manufacturing stages in which a metallization system may be formed on the basis of a metal-containing hard mask material that is patterned by using wet chemical etch recipes, according to further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally contemplates semiconductor devices and manufacturing techniques in which a metal-containing material, such as titanium nitride, tantalum nitride and the like, may have to be patterned during various manufacturing phases, wherein, in some illustrative embodiments, wet chemical etch recipes may be applied. Contrary to conventional strategies, however, a well-defined under-etching of the etch mask may be provided, in some illustrative embodiments, on the basis of an organic material, such as resist material, or generally any appropriate polymer material, so that well-defined and predictable lateral dimensions of the patterned metal-containing material layer may be obtained. It has been recognized that a non-controllable under-etching of the metal-containing material, such as the titanium nitride material, may be avoided or at least significantly reduced during a wet chemical etch process on the basis of an organic mask material when a surface modification is applied to the initially provided metal-containing material, wherein the resulting modified surface layer may have a thickness of 2 nm and less, for instance approximately 1 nm. Without intending to restrict the present application to the following explanation, it is believed that the surface modification may result in a superior adhesion between the modified surface layer and the organic mask material, thereby avoiding or at least significantly reducing the migration of chemicals along an interface between these two materials. In some illustrative embodiments disclosed herein, the surface modification may be provided so as to incorporate oxygen species into the base material, wherein the penetration depth of the oxygen species may be restricted to a desired thickness, thereby obtaining a modified surface layer of well-defined thickness. In some illustrative embodiments, the oxygen incorporation may be accomplished by applying an oxidation process, which, in some illustrative embodiments, may be applied in the presence of a gaseous process atmosphere, which may be established on the basis of a plasma in the presence of oxygen or on the basis of ozone without requiring an additional plasma. In other illustrative embodiments, it has been recognized that, in particular, a wet chemical oxidation on the basis of diluted hydrogen peroxide and/or on the basis of diluted ozone may result in a self-limiting oxidation of, for instance, titanium nitride material, thereby obtaining an oxidized surface layer having a well-defined thickness that is substantially independent of certain process parameters, such as process time and the like. Consequently, in this manner, well-defined overall layer characteristics may be established since the base material of the metal-containing material layer, as well as the resulting modified surface layer, may be provided with well-defined material characteristics, thereby providing superior predictability of the etch results and also providing well-defined material characteristics during the further processing of the device, for instance when forming sophisticated high-k metal gate electrode structures.

In other illustrative embodiments, metal-containing materials, such as titanium nitride, may be patterned on the basis of wet chemical etch recipes in combination with organic mask materials so as to obtain well-defined lateral dimensions, wherein the patterned metal-containing material may then be used as efficient hard mask materials, thereby taking advantage of the superior etch resistivity of such materials with respect to a plurality of plasma assisted etch processes. In this manner, for instance, well-defined device features, such as metal lines, vias and the like, may be provided in sophisticated semiconductor devices on the basis of, for instance, titanium nitride-based hard mask materials, while nevertheless superior patterning efficiency of the hard mask material may be achieved.

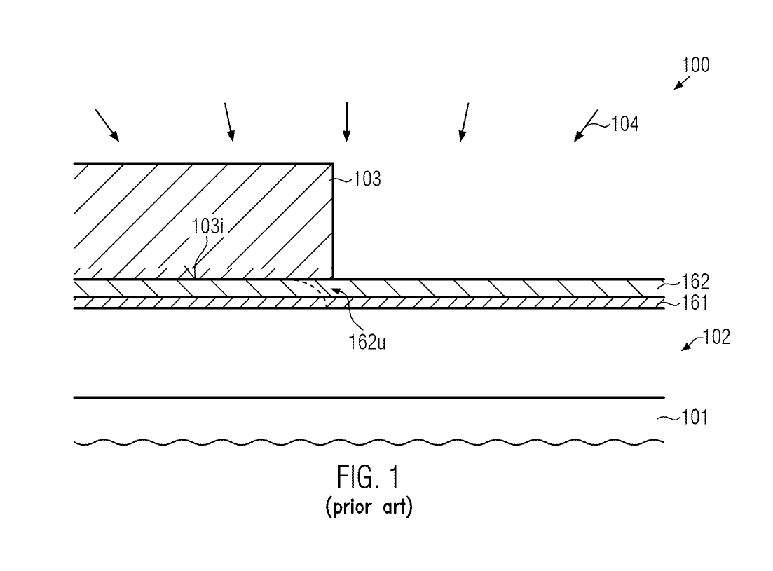

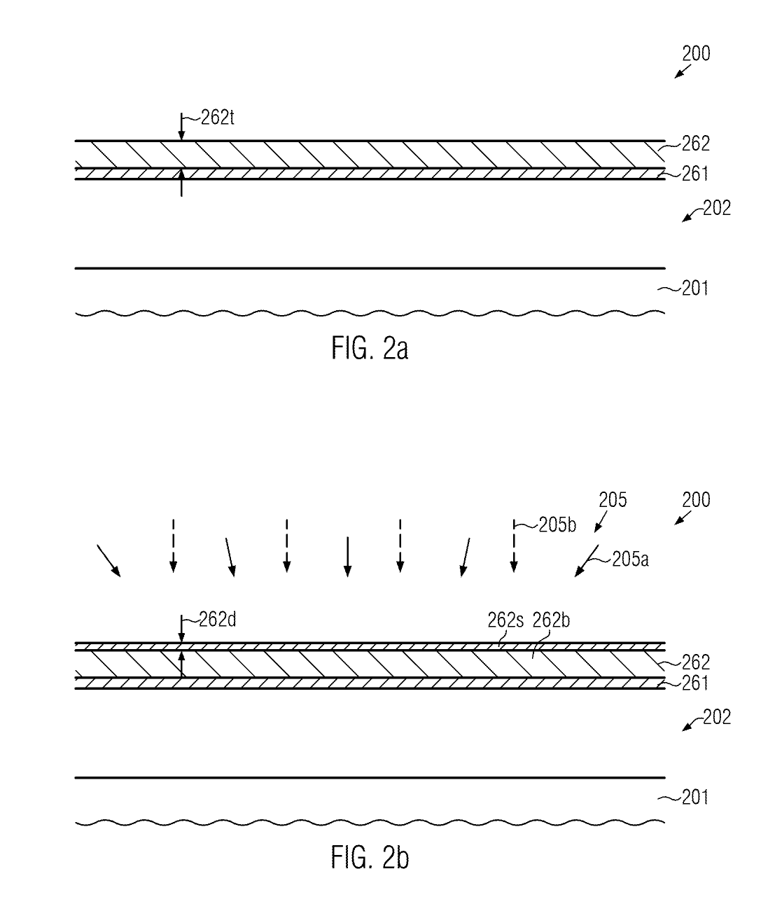

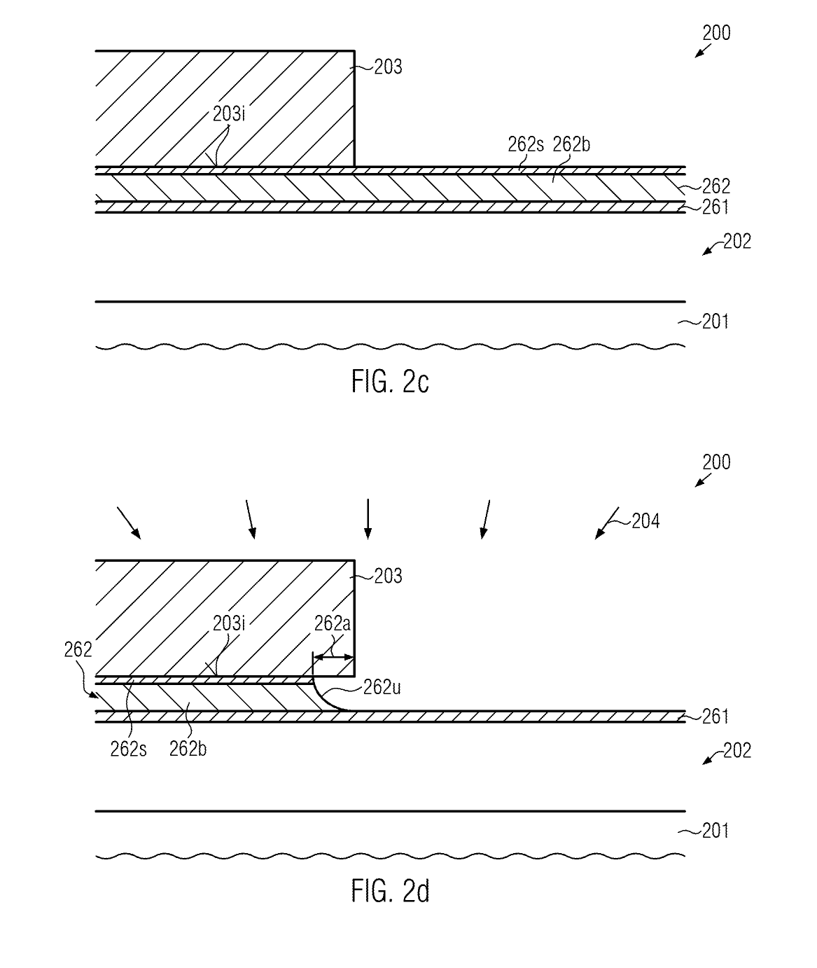

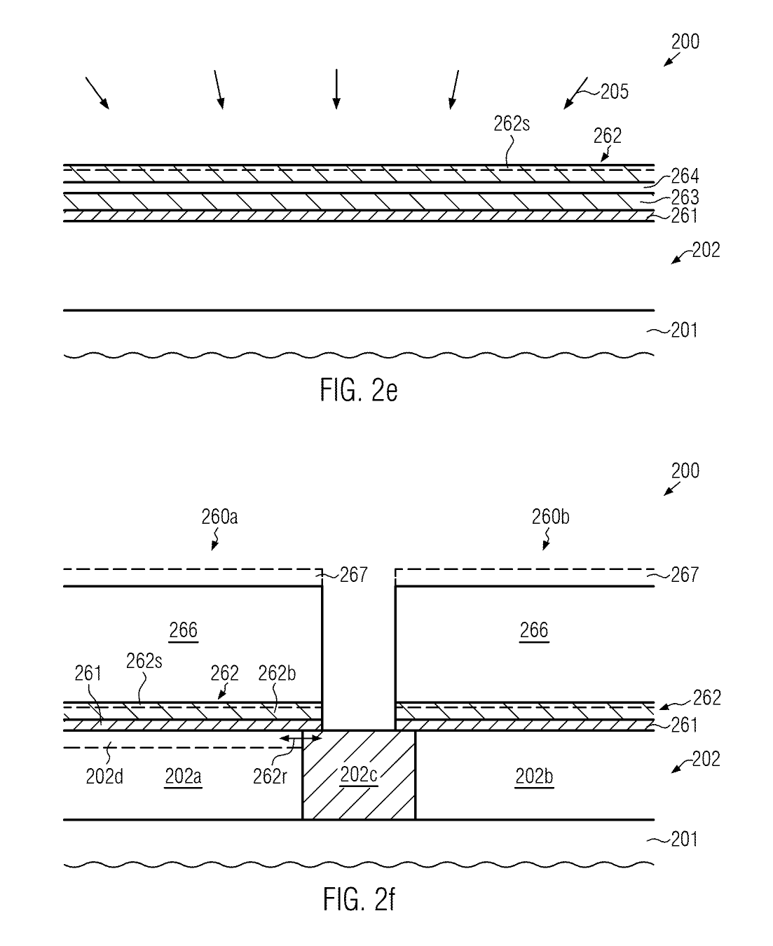

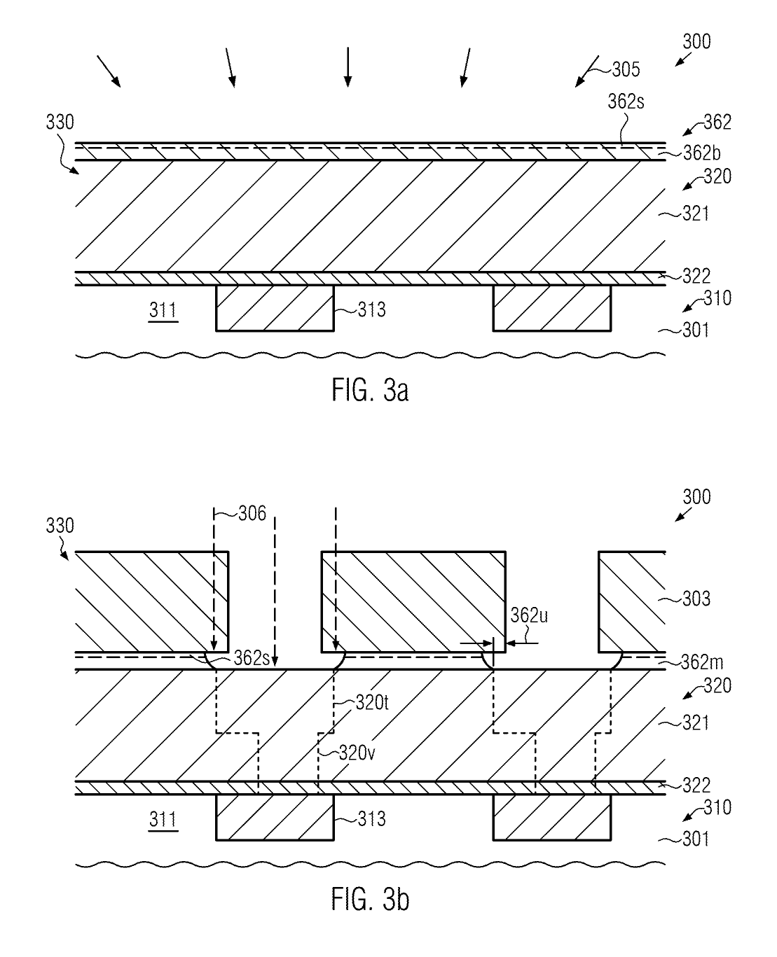

With reference to FIGS. 2a-2f and 3a-3b, further illustrative embodiments will now be described in more detail, wherein reference may also be made to FIG. 1, if appropriate.

FIG. 2a schematically illustrates a cross-sectional view of a semiconductor device 200 comprising a substrate 201 and a semiconductor layer 202 formed above the substrate 201. As previously discussed, the semiconductor layer 202, provided in the form of a silicon material, a silicon/germanium material, or any other appropriate semiconductor material for forming therein and thereon circuit elements, such as field effect transistors, may form a bulk configuration in combination with the substrate 201, while in other cases an SOI architecture may be provided by these components when a buried insulating material (not shown) is formed below the semiconductor layer 202. In some illustrative embodiments, the semiconductor layer 202 may be divided into a plurality of active regions or semiconductor regions (not shown), which are to be understood as semiconductor regions in and above which one or more transistors are to be formed. The lateral delineation of active regions in the layer 202 may be accomplished by providing appropriate isolation regions, as will be discussed later on in more detail. In the embodiment shown, a metal-containing material 262 may be formed above the semiconductor layer 202 and may have to be patterned on the basis of an efficient manufacturing strategy, for instance using organic mask materials, such as resist materials, and a wet chemical etch recipe. In one illustrative embodiment, the metal-containing material layer 262 may be comprised of titanium nitride, which is to be understood as a material comprising nitrogen and titanium, wherein a stoichiometric ratio may vary depending on specific process and device requirements. For example, titanium nitride is known as a well-established material in the semiconductor industry, which may be used for forming conductive barrier materials in combination with other highly conductive materials, such as tungsten, copper, aluminum and the like. Furthermore, titanium nitride is substantially stable at high temperatures, thereby allowing the application of high temperature processes in a further advanced manufacturing stage. In particular due to its conductivity and the temperature characteristics, titanium nitride may frequently be used in process strategies for forming sophisticated high-k metal gate electrode structures. For example, titanium nitride may be efficiently used as a conductive cap material during high temperature processes for adjusting material characteristics, for instance for adjusting the threshold voltage characteristics of gate electrode structures and associated transistors, while at the same time acting as an efficient electrode material due to the moderately high conductivity of titanium nitride, for instance compared to even highly doped polysilicon material. In the embodiment shown, a further material layer 261 may be provided between the semiconductor layer 202 and the metal-containing material layer 262, wherein, in some illustrative embodiments, the material layer 261 may be provided as a gate dielectric layer providing the required base characteristics of a gate dielectric material for gate electrode structures still to be formed. As discussed above, in some illustrative embodiments, the material layer 261 may comprise a high-k dielectric material, for instance one or more of the components identified above, possibly in combination with a conventional dielectric material, such as silicon dioxide, silicon oxynitride and the like. In this manner, a required physical thickness may be obtained, for instance with respect to achieving a required behavior with respect to leakage currents, while at the same time, nevertheless, a desired high capacitive coupling may be achieved due to the high dielectric constant. For example, the layer 261 when provided in the form of a gate dielectric material may have a thickness in the range of one to several nanometers, depending on the overall device requirements. In this case, the metal-containing material layer 262 may be provided with a thickness of several nanometers, for instance with a thickness of 1-5 nm, while it is to be understood that any other thickness value may be used, depending on the process and device requirements. In some illustrative embodiments, the initial thickness 262t of the metal-containing material layer 262 may be selected such that after performing a surface treatment and forming a modified surface layer of well-defined characteristics, in total the required material characteristics of the layer 262 may be achieved. In other cases, the initial layer thickness 262t is selected such that a desired modified surface layer may be formed in a later manufacturing stage, which may then be removed so as to provide the layer 262 with a reduced thickness, which is then appropriate for the further processing and in view of the required device characteristics.

The semiconductor device 200 as shown in FIG. 2a may be formed on the basis of well-established process techniques, for instance by laterally delineating the semiconductor layer 202 (not shown) on the basis of well-established isolation structures (not shown), followed by the formation of the layer 261, which may include oxidation processes or other surface treatments, when a conventional dielectric material is to be provided, followed by the deposition of any appropriate high-k dielectric material, which may include CVD processes, ALD processes and the like. Thereafter, the layer 262 may be formed, for instance, by ALD, PVD and the like.

FIG. 2b schematically illustrates the semiconductor device 200 in a further advanced manufacturing stage in which a surface treatment 205 may be applied to the layer 262 in order to form a modified surface layer 262s, while the remaining initial material of the layer 262 may remain substantially non-modified, thereby forming a base layer 262b. In some illustrative embodiments, the modified surface layer 262s may be provided with a thickness 262d, which is highly uniform and thus may provide superior process conditions during the further processing of the device 200. For example, in some illustrative embodiments, the thickness 262d of the surface layer 262s may be 5 nm or less, while in other cases an even further reduced thickness of approximately 1.5 nm and less may be achieved upon forming the modified surface layer 262s. In some illustrative embodiments, the surface treatment 205 may comprise a process or process sequence 205a, in which oxygen is incorporated into the layer 262 in order to form the modified surface layer 262s. In one embodiment, the process 205a may thus represent an oxidation process that is performed on the basis of a wet oxidation process ambient in which one or more oxidizing agents may be provided in the form of liquid solution, which is brought into contact with an exposed surface of the initial layer 262. In some illustrative embodiments, the wet oxidation process may be performed on the basis of diluted hydrogen peroxide (H₂O₂), while in other illustrative embodiments an aqueous solution including ozone may be used for performing a wet oxidation process. For example, by using ozone-based aqueous solutions, a substantially self-limiting oxidation behavior may be accomplished, thereby restricting the thickness 262d of the oxidized surface layer 262s to approximately 1 nm. It should be appreciated that appropriate recipes and process parameters may be readily determined on the basis of experiments, for instance by preparing appropriate hydrogen dioxide-based aqueous solutions and determining a corresponding removal rate for a given material composition of the layer 262. Furthermore, appropriate process temperatures may be selected so as to comply with the overall process and device requirements. Similarly, the concentration of ozone in a corresponding aqueous solution during the process 205a may also be selected in accordance with process requirements on the basis of experiments, wherein, however, due to the self-limiting nature of the corresponding oxidation process, substantially the same thickness 262d may be obtained for a wide range of process times. For example, generally the process 205a may be applied on the basis of a process time in the range of several seconds to 60 seconds or more, depending on the recipe used, wherein the resulting thickness 262d may be determined in advance by determining the corresponding oxidation rate. Hence, irrespective of the characteristics of the oxidation process 205a, a well-controlled and highly predictable thickness 262d of the surface layer 262s may be obtained. Consequently, the overall characteristics of the layer 262 after the treatment 205, i.e., the thickness and characteristics of the layer 262b, 262s may be adjusted with a high degree of precision.

In other illustrative embodiments, the surface treatment 205 may comprise a process 205b performed on the basis of a gaseous process atmosphere. For example, in some illustrative embodiments, the process 205b may be applied by establishing a plasma ambient in the presence of oxygen gas, thereby obtaining an oxidizing ambient for forming the surface layer 262s. Oxygen-based plasma recipes are readily available or may be readily established by performing experiments, wherein process parameters, such as flow rates of the precursor gases, such as oxygen and possibly any carrier gases, such as argon, nitrogen and the like, and plasma power, may be selected for a given chamber configuration of a plasma reactor in order to obtain a well-defined oxidation rate. In this case, also a well-defined thickness of the layer 262s may be adjusted. In still other cases, the gaseous ambient of the process 205b may be established on the basis of appropriate gas mixtures, for instance including ozone, which may thus also result in an appropriate incorporation of oxygen into the layer 262s. Also in this case, appropriate process parameters may be readily determined on the basis of experiments in order to determine a desired oxidation rate for a given material composition of the layer 262. For example, for a titanium nitride base material, a surface layer 262s may represent a TINO layer wherein, in particular in plasma-based processes, the oxygen contents may be determined by the plasma parameters.

FIG. 2c schematically illustrates the semiconductor device 200 in a further advanced manufacturing stage in which an etch mask 203 may be formed on the layer 262, that is, on the modified surface layer 262s. In some illustrative embodiments, the etch mask 203 may be comprised of an organic material, that is, a resist material, i.e., a radiation sensitive material, and/or any appropriate polymer material may be used for forming the mask 203, which may be accomplished by applying well-established lithography techniques. That is, one or more organic mask materials may be applied and may be appropriately treated, for instance, by elevated temperatures and the like, followed by exposure with radiation and development, wherein, if required, additional treatments may be used in order to obtain the desired lateral dimensions of the etch mask 203. Consequently, the mask 203 and the modified surface layer 262s may form an interface 203i which, due to the presence of the surface layer 262s, may have superior adhesion compared to an organic mask material, which may be directly applied to the base material of the layer 262, as is, for instance, preserved in the layer 262b. Thus, the resist material or generally the organic material of the etch mask 203 may be applied on the layer 262 without requiring any additional queue time, as is frequently necessary in conventional approaches, so that superior flexibility for scheduling the overall process flow may be achieved, while also increased throughput for a given amount of available process tools may be obtained.

FIG. 2d schematically illustrates the semiconductor device 200 when exposed to an etch process 204, which, in some illustrative embodiments, may be applied in the form of a wet chemical etch process. For example, the etch process 204 may be performed on the basis of APM, which is well known as a highly efficient etch agent for removing titanium nitride material. It should be appreciated, however, that any other wet chemical etch recipes may be applied, for instance based on SPM (sulfuric acid/hydrogen peroxide mixture) and the like, depending on the material characteristics of the layer 262. Due to the isotropic nature of the process 204, a certain degree of under-etching 262u may be created, depending on the overall thickness of the layer 262. That is, since a given etch time for a specific etch recipe of the process 204 may be required for completely removing exposed portions of the layer 262, a corresponding exposure to the etch ambient may also occur below the etch mask 203, thereby resulting in the under-etched area 262u. Contrary to conventional strategies, however, the lateral extension of the under-etched area 262u may be highly controllable since the superior interface characteristics at the interface 203i may significantly reduce or substantially completely avoid the migration of etch chemicals along the interface 203i, thereby avoiding or at least significantly reducing an etch attack of the layer 262s along the interface 203i, except at the lateral edges of the etch mask 203. Hence, for a total thickness of approximately 5 nm of the layer 262, the lateral extension 262a of the under-etched area 262u, at least at the interface 203i, may be on the same order of magnitude, wherein the exact amount is highly predictable on the basis of the known removal rate and the applied etch time. Consequently, the lateral dimensions of the patterned layer 262 are well controllable during the etch process 204, while also superior surface characteristics may be obtained after the removal of the etch mask 203 due to the superior characteristics of the interface 203i.

Consequently, the further processing may be continued on the basis of well-defined lateral dimensions of the patterned layer 262, for instance by forming additional layers of a gate layer stack, which may then be subsequently patterned by well-established process strategies.

FIG. 2e schematically illustrates the semiconductor device 200 according to further illustrative embodiments in which the metal-containing material layer 262 may be exposed to the surface treatment 205, while additional material layers may be present, depending on the overall process strategy. For example, the gate dielectric layer 261 may be provided in combination with one or more material layers that may be required for appropriately adjusting the characteristics of gate electrode structures still to be formed. As shown, a metal-containing material layer 263 may be provided, for instance in the form of titanium nitride and the like, possibly in combination with an additional layer 264, which may comprise appropriate work function metal species as required for a specific type of transistor. For example, the layer 264 may comprise lanthanum, aluminum and the like in order to appropriately position the metal species in the layer 263 and/or in the layer 261. Moreover, the layer 262 may act as an efficient cap layer for providing well-defined diffusion characteristics during a subsequent high temperature process so as to diffuse metal species from the layer 263 into one or more of the underlying material layers. In other cases, the stack of layers as shown in FIG. 2e may be considered appropriate for providing required electronic characteristics for one type of gate electrode structure, while the layer stack, or at least a significant portion thereof, has to be removed from other device areas in order to provide a further layer stack of different electronic characteristics. Also in this case, an etch mask has to be formed above the layer 262 in order to perform one or more patterning processes so as to adjust the lateral dimensions of at least some of the layers 264, 263, 261. Hence, also in this case, the surface treatment 205 may be applied so as to form the modified surface layer 262s, thereby enabling a direct formation of an organic mask material on the layer 262s, which also provides superior interface characteristics, as discussed above. Thereafter, the further processing may be continued by using the organic mask material having the superior adhesion characteristics and removing one or more of the exposed layer portions. Thereafter, further metal-containing material layers may be applied and may be patterned, which may also include titanium nitride or any other appropriate cap materials, wherein a patterning thereof may be accomplished by applying the surface modification process 205 and a subsequent application of an organic mask material, as discussed above.

FIG. 2f schematically illustrates the semiconductor device 200 in a further advanced manufacturing stage. As shown, a gate electrode structure 260a may be formed on an active region 202a and a portion of an isolation region 202c. Similarly, a gate electrode structure 260b may be formed on an active region 202b and a portion of the isolation structure 202c. The gate electrode structure 260a may comprise the gate dielectric layer 261 in combination with the metal-containing material layer 262 which, in some illustrative embodiments, may still comprise the modified surface layer 262s in combination with the base layer 262b. Similarly, the gate electrode structure 260b may comprise the layers 261 and 262 wherein, however, the layers 262 and/or 261 of the gate electrode structure 260b may have different characteristics compared to the layers 261 and/or 262 of the gate electrode structure 260a. For example, as discussed above, different metal species may be provided in the layers 261 and/or 262 of the individual gate electrode structures in order to obtain different characteristics, if the gate electrode structures 260a, 260b correspond to different types of transistors to be formed in and above the active regions 202a, 202b, respectively. To this end, frequently, an additional semiconductor material, such as a silicon/germanium material and the like, as indicated by 202d, may be provided in one of the active regions 202a, 202b so as to obtain a desired band gap offset between different types of transistors, such as P-channel transistors and N-channel transistors, respectively.

Furthermore, the gate electrode structures 260a, 260b may comprise a further electrode material 266 provided in the form of a silicon material, a silicon/germanium material and the like. Furthermore, in the manufacturing stage shown, the gate electrode structures 260a, 260b may have appropriate lateral dimensions, i.e., at least in a transistor width direction, which is to be understood as the horizontal extension in FIG. 2f.

The semiconductor device 200 as shown in FIG. 2f may be formed on the basis of the following processes. The active regions 202a, 202b and the isolation region 202c may be formed on the basis of well-established process strategies including the formation of appropriate trenches in the initial semiconductor layer, followed by the incorporation of an appropriate dielectric fill material, such as silicon dioxide and the like. Prior to or after forming the isolation region 202c, the basic electronic characteristics may be established in the active regions 202a, 202b by using implantation techniques in combination with appropriate masking regimes. Prior to or after forming the isolation region 202c, furthermore the additional semiconductor material 202d, if required, may be formed by epitaxial growth techniques based on well-established recipes. Thereafter, the layers 261, 262 may be formed, as discussed above, and may be patterned so as to obtain appropriate lateral dimensions, for instance in the transistor width direction, as indicated in FIG. 2f. That is, typically the layer 262 has to be laterally restricted above corresponding isolation regions, such as the isolation region 202c, if different characteristics may be required above different active regions, as discussed above. Thereafter, further deposition and patterning strategies may be applied, if required, in order to provide the layer 262 with the required characteristics specifically adapted to the various active regions, as for instance shown in FIG. 2f. It should be appreciated, however, that also process strategies may be applied in which a plurality of layers have to be patterned, for instance on the basis of the layer 262 and the process strategy described above with reference to FIG. 2e, in order to obtain the desired electronic characteristics of the layers 261 and/or any underlying layers, while the layer 262 may have to be removed in a later process stage.

It should be noted that, in some illustrative embodiments (not shown), the gate dielectric layer 261 may be provided in combination with a metal-containing material layer that has not been patterned on the basis of the above-described process sequence. To this end, the characteristics of the layer 261 may have been adjusted in an earlier stage by incorporating appropriate metal species, for example by diffusion, which in turn may require the patterning of a metal-containing material layer so as to diffuse different types of metal species into lower lying layers, such as the layer 261. In this case, the patterning of any such diffusion layers may be accomplished on the basis of process techniques as are described in the context of the layer 262, thereby also providing superior process robustness and efficiency. Thereafter, any appropriate metal-containing material layer may then be applied commonly for differently prepared underlying layers, such as the layer 261 comprising different types of metal species, wherein such a common layer may be provided, for instance, in the form of titanium nitride, which may then be patterned along with the further electrode material 266, however without requiring a direct contact with an organic mask material.

In the embodiment shown, however, a process strategy may be applied in which the layers 262 of the gate electrode structures 260a, 260b may have been patterned on the basis of a direct contact with an organic mask material, as discussed above. Moreover, in the embodiment shown, the modified surface layer 262s may still be present in the layer 262 wherein, due to the reduced thickness thereof, a pronounced influence on the overall electronic characteristics, for instance with respect to the overall conductivity, may be negligible. In other illustrative embodiments (not shown), the modified surface layer 262s may be removed, for instance, by applying a non-masked wet chemical etch process, for instance based on APM and the like, prior to depositing the further electrode material 266, if a reduced overall conductivity of the surface layer 262s is considered inappropriate. In this case, the layer 262s may be efficiently removed while reliably preserving at least a significant portion of the base layer 262b, which may be accomplished by selecting appropriate etch parameters, for instance selecting an appropriate etch time for a given removal rate.

Thereafter, the electrode material 266 may be applied, for instance by well-established CVD techniques, followed by the deposition of any further sacrificial materials, such as a hard mask material 267, for instance provided in the form of silicon nitride, silicon dioxide and the like. Thereafter, the resulting layer stack may be patterned on the basis of complex lithography and etch techniques, possibly comprising a double exposure/double etch strategy. In this manner, well-defined lateral dimensions of the gate electrode structures 260a, 260b may be obtained wherein a gate length, i.e., the lateral dimension of the gate electrode structures 260a, 260b in a direction perpendicular to the drawing plane of FIG. 2f, may be 50 nm and significantly less in sophisticated applications.

Due to the well-controllable and precise patterning of the layer 262, for instance along the transistor width direction, i.e., the horizontal direction in FIG. 2f, a non-desired under-etching and thus a non-predictable lateral removal of the layer 262 may be avoided, as discussed above, thereby, for instance, ensuring that the material 262 may be preserved above a portion of the isolation regions 202c, as is required for defining a gate width that is determined by the lateral dimension of the underlying active region. Hence, upon providing the materials 266, 267 and patterning the same, appropriate and well-defined gate dimensions in the width direction may be achieved. For example, in conventional strategies, the patterning of the layer 262 prior to providing the materials 266, 267 may result in undue under-etching of the corresponding metal-containing material layer, as discussed above, which may even result in a recessing or withdrawal of this material from an edge portion of the active regions. In this case, the width dimension of the resulting gate electrode structure may not entirely cover the corresponding active region so that the resulting width of the gate electrode structure would be less than desired and would thus result in significant variations of the resulting transistor characteristics.

Hence, a corresponding recessing 262r of at least the material 262 may be reliably suppressed by applying the above-described process sequence using the modified surface layer 262s having the superior adhesion characteristics with respect to organic mask materials.

FIG. 3a schematically illustrates a cross-sectional view of the semiconductor device 300 in an advanced manufacturing stage in which a metal-containing material, such as titanium nitride and the like, may have to be patterned so as to provide well-defined lateral dimensions of the metal-containing material layer. As shown, the device 300 may comprise a substrate 301, which may be any appropriate carrier material, as for instance already discussed above with reference to the semiconductor devices 100 and 200. In and above the substrate 301, an appropriate semiconductor layer (not shown) may be provided, which may be used for forming semiconductor-based circuit elements. Moreover, a metallization system 330 may be formed above the substrate 301 and may comprise a first metallization layer 310 including an appropriate dielectric material 311 and a plurality of metal regions 313, for instance provided in the form of metal lines and the like. Furthermore, a further metallization layer 320, which may comprise a dielectric material 321 in combination with a dielectric cap layer 322 may be formed above the metallization layer 310. The metallization layer 320 may represent a level of the system 330 in which a plurality of metal regions may have to be provided so as to appropriately connect to one or more of the metal regions 313 of the lower metallization layer 310. In sophisticated semiconductor devices, the reduced lateral dimensions of any semiconductor-based circuit elements, such as field effect transistors and the like, may also require reduced lateral dimensions of metal features to be formed above the semiconductor-based circuit elements in order to appropriately electrically connect the individual circuit elements. Thus, in sophisticated manufacturing strategies, appropriate hard mask regimes may be applied in order to pattern the dielectric materials of a specific metallization level. For example, a metal-containing material layer 362 may be formed above the dielectric material 321 and may, in some illustrative embodiments, be comprised of titanium nitride or other metal-containing materials, such as tantalum nitride and the like, well known to have a high etch resistivity with respect to a plurality of plasma assisted etch processes, as may be required for patterning the dielectric materials 321, such materials may preferably be used as hard mask materials since a reduced thickness of the hard mask layer may be sufficient for providing the required etch stop capabilities, thereby allowing an efficient removal of the hard mask material without unduly affecting the underlying dielectric material 321. In order to enable an efficient patterning of the material 362 on the basis of wet chemical etch chemistries, a surface treatment 305 may be applied in order to form a well-defined modified surface layer 362s, while a remaining portion 362b may have substantially the initial material characteristics of the layer 362. The surface treatment 305 may be performed on the basis of etch recipes and process strategies as are previously discussed with reference to the process 205 (FIG. 2b).

FIG. 3b schematically illustrates the semiconductor device 300 in a further advanced manufacturing stage. As illustrated, an etch mask 303 may be provided in the form of an organic material, such as a resist material, possibly in combination with other organic materials, such as optical planarization materials and the like, wherein the surface layer 362s may provide superior interface characteristics, for instance with respect to superior adhesion, as is also discussed above. Consequently, the underlying hard mask material may be patterned into a hard mask 362m on the basis of a wet chemical etch process, which may result in well-defined under-etched areas 362u. Consequently, for a given lateral configuration of the etch mask 303, a precisely defined lateral configuration of the hard mask 362m may be obtained, since the under-etched areas 362u may have a well-predicted and well-controllable lateral extension, as discussed above. Hence, based on the hard mask 362m, for instance after the removal of the mask 303, appropriate anisotropic etch processes 306 may be applied so as to etch into and through the dielectric materials 321, 322 on the basis of well-established etch recipes. In this manner, trenches 320t and vias 320v may be formed in the materials 321, 322 with well-defined lateral dimensions based on the hard mask 362m, which in turn may be patterned on the basis of a highly efficient patterning regime.

As a result, the present disclosure provides manufacturing techniques and semiconductor devices in which metal-containing materials such as titanium nitride and the like may be patterned on the basis of wet chemical etch techniques with an etch mask comprised of organic material that is directly applied on the metal-containing material. In order to enhance the interface characteristics, a modified surface layer may be formed, for instance, by a controlled oxidation process, thereby avoiding or at least significantly reducing the migration of wet chemical agents along the interface in a non-controlled manner. Consequently, lateral dimensions obtained by a lithography process may be translated into the underlying metal-containing material in a reliable and predictable manner without requiring an additional waiting time after the deposition of the metal-containing material layer and the organic material of the etch mask. Furthermore, additional treatments for promoting the surface adhesion of a resist material may not be required. In some illustrative embodiments, the surface modification or treatment may be performed as a substantially self-limiting oxidation process.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
performing a surface treatment on a metal-containing material layer formed above a substrate of a semiconductor device, said surface treatment resulting in an incorporation of oxygen into said metal-containing material layer;
forming an organic mask on a surface of said metal-containing material layer after said surface treatment; and
performing a wet chemical etch process and using said organic mask as an etch mask so as to pattern said metal-containing material layer.

2. The method of claim 1, wherein said conductive metal-containing material layer comprises nitrogen.

3. The method of claim 2, wherein said metal-containing material layer comprises titanium.

4. The method of claim 1, wherein performing said surface treatment comprises performing a wet oxidation process.

5. The method of claim 4, wherein said wet oxidation process is performed by using at least one of hydrogen peroxide (H₂O₂) and a mixture of water and ozone.

6. The method of claim 1, wherein performing said surface treatment comprises performing an oxidation process in a gaseous process atmosphere.

7. The method of claim 6, further comprising establishing a plasma in the presence of oxygen in said gaseous process atmosphere.

8. The method of claim 6, wherein said gaseous process atmosphere is established by using gaseous ozone.

9. The method of claim 1, wherein said metal-containing electrode material comprises titanium and nitrogen.

10. The method of claim 1, wherein performing said surface treatment comprises forming an oxygen-containing layer in said metal-containing material layer with a thickness of approximately 2 nm or less.

11. The method of claim 1, further comprising forming a gate dielectric layer prior to forming said metal-containing material layer, wherein said gate dielectric layer comprises a high-k dielectric material.

12. The method of claim 11, further comprising forming a semiconductor electrode material above said metal-containing material layer.

13. The method of claim 1, further comprising performing a plasma assisted etch process and using said patterned metal-containing material layer as a hard mask.

14. A method, comprising:
forming an oxidized surface layer in a titanium and nitrogen containing material;
forming an etch mask on said oxidized surface layer; and
performing an etch process in the presence of said etch mask so as to pattern said titanium and nitrogen containing material.

15. The method of claim 14, wherein performing said etch process comprises performing a wet chemical etch process.

16. The method of claim 14, wherein said oxidized surface layer is formed with a thickness of approximately 2 nm or less.

17. The method of claim 16, wherein forming said oxidized surface layer comprises performing a wet oxidation process.

18. The method of claim 14, wherein forming said oxidized surface layer comprises performing an oxidation process in a gaseous process atmosphere.

19. The method of claim 14, further comprising forming a gate dielectric layer prior to forming said titanium and nitrogen containing material, wherein said gate dielectric layer comprises a high-k dielectric material.

20. A semiconductor device comprising:
a gate electrode structure comprising a high-k gate insulation layer, a metal-containing first electrode material formed on said high-k gate insulation layer and a second electrode material formed above said metal-containing first electrode material, said metal-containing first electrode material comprising an oxygen-containing surface layer having a thickness of approximately 2 nm or less.
